(19) United States
(12) Patent Application Publication
(10) Pub. No.: US 2025/0250673 A1
(43) Pub. Date: Aug. 7, 2025

(54) ALD Deposition Utilizing MoO2Cl2 and MoO2Br2

(71) Applicant: Versum Materials US, LLC, Tempe, AZ (US)

(72) Inventors: Michael Miller, San Jose, CA (US); Randall Higuchi, Santa Clara, CA (US); Thong Ngo, San Jose, CA (US); Angelica Azcatl-Zacatzi, San Jose, CA (US); Xinjian Lei, Vista, CA (US)

(21) Appl. No.: 18/702,896

(22) PCT Filed: Oct. 26, 2022
(86) PCT No.: PCT/US2022/078674

§ 371 Date: Apr. 19, 2024

Related U.S. Application Data
(60) Provisional application No. 63/263,899, filed on Nov. 11, 2021.

(51) Int. Cl. C23C 16/455; C23C 16/30; C23C 16/44

(52) U.S. Cl. CPC C23C 16/45553; C23C 16/305; C23C 16/4408; C23C 16/45536

(57) ABSTRACT

The disclosed and claimed subject matter relates to atomic layer deposition (ALD) of 2D MoX₂ (X=S, Se or Te) utilizing one or more of MoO₂Cl₂ and MoO₂Br₂ as the Mo-precursor with alkyl-chalcogenide, alkyl-dichalcogenide, and/or dihydro-chalcogenide precursors while maintaining the process in a self-limiting-layer-synthesis growth mode or a self-limiting-layer-synthesis-like growth mode.

### BACKGROUND

### Field

The disclosed and claimed subject matter relates to atomic layer deposition (ALD) of 2D MoX₂ (X=S, Se or Te) utilizing one or more of MoO₂Cl₂ and MoO₂Br₂ as the Mo-precursor with alkyl-chalcogenide, alkyl-dichalcogenide, and/or dihydro-chalcogenide precursors while maintaining the process in a self-limiting-layer-synthesis growth mode or a self-limiting-layer-synthesis-like growth mode.

### Related Art

Various precursors may be used to form metal-chalcogenide thin films and a variety of deposition techniques can be employed. Such techniques include reactive sputtering, ion-assisted deposition, sol-gel deposition, chemical vapor deposition (CVD) (including metalorganic CVD or MOCVD), atomic layer deposition (ALD). CVD and ALD type processes are increasingly used as they have the advantages of enhanced compositional control, high film uniformity and effective control of doping.

ALD deposition requires an evacuated reaction chamber with precursor lines having the ability to flow into the reaction chamber using either (i) the vapor pressure (“vapor draw”), (ii) a carrier flowing through the precursor ampule (“bubbling”) or (iii) gas flow from a bottle, tank or other source. In operation, a substrate is placed into the reaction chamber and a first precursor/reactant is flowed into the chamber for a time sufficient to saturate the substrate surface (“1^{st} precursor pulse”) before evacuating the chamber using a purge gas flow. After the purge is finished, a second precursor/reactant is flowed into the chamber for a time sufficient to saturate the substrate surface that has previously been coated with first precursor molecules (“2^{nd} precursor pulse”). This is followed by a second purge step, which finishes the cycle for a two-precursor reaction. At this point, the cycle repeats at the beginning, and runs as many times as required to meet the desired film thickness. When operating at elevated pressure, a pressure stabilization step can be added between the end of the purge and the beginning of the next pressure precursor pulse. In general, ALD mode requires the precursors to not be decomposing or decomposed. For the vast majority of precursors this introduces a CVD component into the ALD process, negatively impacting the ALD properties of the process and the purity of the deposited film. The growth curve (thickness vs ALD cycles) is most commonly a linear curve or if there is some CVD component it might be a supra-linear growth curve (has quadratic or higher terms of ALD cycles in fitting the thickness vs ALD cycles). It is virtually never (at least intentionally) an asymptotic curve or sublinear curve.

CVD is another chemical process whereby precursors are used to form a thin film on a substrate surface. In a typical CVD process with two or more precursors, the precursors are introduced into the chamber together or at least with planned overlap so that they will react in the gas phase or at the wafer surface. There are CVD processes with one precursor that decomposes to yield a deposited film on the substrate, such as SiH₄ decomposing to yield a Si film. In either case, the precursor or precursors are passed over the surface of a substrate (e.g., a wafer) in a low pressure or ambient pressure reaction reactor. The precursors react and/or decompose in the gas phase or on the wafer surface, and this material deposits on the substrate surface creating a thin film of deposited material. There can be a surface reaction in CVD, but most CVD processes involve pre-reaction or pre-decomposition in the gas phase as opposed to ALD where the deposition reactions are entirely surface reactions. Volatile by-products are removed by gas flow through the reaction reactor. The deposited film thickness can be difficult to control because it depends on coordination of many parameters such as temperature, pressure, gas flow volumes and uniformity, chemical depletion effects, and time. CVD processes can be run thermally or in plasma enhanced modes, and usually require higher temperatures (at the edge of precursor decomposition or higher) and/or energized plasma conditions to assure decomposition and/or gas phase reaction; therefore, they usually require more complex hardware than thermal ALD processes. In CVD processes, more precursor (longer pulses or more flux) equals more film without any asymptotic limit to growth or a soft saturation (a saturation to much slower linear growth) with increased precursor time or flux.

The continual decrease in the size of microelectronic components, such as semi-conductor devices, presents several technical challenges and has increased the need for improved thin film technologies. In particular, thin, high-mobility, semiconductor deposition with excellent conformality and a self-limiting growth to a uniform thickness to enable enhancement of transistor channels in a variety of devices is important, where thickness and uniformity control is imperative, such as 3D NAND cells, and very advanced logic transistors, including fin FETs and GAA devices where the Si body thickness reaches 2.5 nm or less. CVD and ALD are specifically attractive for fabricating conformal transition metal dichalcogenide (TMD) films on substrates, such as silicon, silicon oxide, metal nitrides, metal oxides and other layers. As noted above, in these techniques, a vapor of a volatile metal complex is introduced into a process reactor where it either reacts in the gas phase and contacts the surface of a silicon wafer whereupon a chemical reaction occurs that deposits a thin film (for example, in CVD, disilane+H2 gas can be injected into a thermal CVD chamber at with the wafer heated to deposition temperature for as long as desired), or individual precursors react on the surface in separate steps within the reaction sequence (for example, in ALD, a trimethylaluminum pulse+purge can be followed by an H₂O pulse+purge, and repeated for as many cycles as desired). CVD occurs if the precursor reacts at the wafer surface either thermally or with a reagent added simultaneously into the process reactor and the film growth occurs in a steady state deposition. CVD can be applied in a continuous or pulsed mode to achieve the desired film thickness and contamination levels. In ALD, the precursor is chemisorbed onto the wafer as a self-saturating monolayer, excess unreacted precursor along with reaction byproducts is purged away with an inert gas, then an excess of a reactant reagent is added to react with the monolayer of chemisorbed precursor to form a material (metal, nonmetal, dielectric, etc.). This inert gas and/or gases is/are understood to be one of nitrogen, argon, neon, helium, krypton, or xenon, or a mixture of any combination of these gases in any fractional quantities. Excess reagent and reaction byproducts are then purged away with inert gas. This cycle can then be repeated multiple times to build up the film to a desired thickness with atomic precision since the chemisorption of precursor and reagent are self-limiting, producing a thickness vs ALD cycles growth curve that it linear. ALD provides the deposition of ultra-thin yet continuous films with precise control of film thickness, excellent uniformity of film thickness and outstandingly conformal film growth to evenly coat deeply etched and highly convoluted structures such as interconnect vias and trenches. Thus, ALD is typically preferred for deposition of thin films on features with high aspect ratio. However, ALD growth of most known MoX₂ films could only be accomplished at temperatures below about 350° C. (except MoCl₅+H₂S), and these lower temperatures resulted in inferior stoichiometry and/or inferior crystallinity, which ruled these ALD processes out.

MoCl₅+H₂S has been identified in literature of a process that can be grown in a “self-limiting-layer-synthesis” deposition mode, which is when the growth curve is not linear or supra-linear, but instead thickness saturates asymptotically with increasing ALD cycles for MoCl₅+H₂S in ALD operation mode (DOI: 10.1038/srep1875); however, no additional examples of such a process can be found. Additionally, one would expect that if such processes were to be identified, they would be among the molybdenum halide precursors, such as other molybdenum chlorides, fluorides, bromides, or iodides rather than a precursor with two thirds of the Mo bonding taken up by oxygen atoms like MoO₂Cl₂. Thus, until now the ability to grow a self-limiting-layer-synthesis MoX₂ films at higher temperatures was limited to using MoCl₅+H₂S→MoS₂. This not only has limited the X in MoX₂, but also has yielded a process with a much larger corrosivity/acidity towards the ALD or CVD chamber hardware materials than is the case with MoO₂Cl₂.

It is highly desirable to be able to achieve growth of Mo based 2D TMD films (other than MoS₂ films) utilizing new precursor sets in an ALD mode of operation. Doing so enables higher temperatures to be used than are currently known and described for depositions of ALD films while also utilizing a broad variety of chalcogenide precursors. Growing Mo based 2D TMD films in a way that also allows growth via “self-limiting-layer-synthesis” deposition mode or “self-limiting-layer-synthesis-like” deposition mode (where the thickness has a soft saturation with ALD cycles rather than a purely asymptotic curve) allows control of the number of monolayers and improvement in the grain size and overall semiconducting quality of the films. The key here is balancing the relative rates of deposition components and etch components of the growth process, which can be modulated by changing chalcogenide precursors. Using MoO₂Cl₂ as an ALD molybdenum precursor for 2D TMD growth enables deposition and etch rates that makes every chalcogenide precursor described herein exhibit self-limiting-layer-synthesis growth or self-limiting-layer-synthesis-like growth for the resulting 2D TMDs. In addition, the deposited films also exhibit substantially lower etch rates than previously used MoCl₅ precursors used in TMD processes.

Given the above, the disclosed and claimed subject matter enables self-limiting Mo-based TMD films to be formed at desirable operating conditions. In particular, it provides methodologies for growing different Mo-films and/or different film thicknesses at the same or similar deposition conditions (e.g., temperature, pressure, flow rates, ampule temperatures, etc.) used for depositing MoCl₅+H₂S without the inherent limitations of molybdenum pentachlorides corrosivity and being limited to only MoS₂ in terms of TMDs.

### SUMMARY

In one embodiment, the disclosed and claimed subject matter relates to ALD deposition processes using one or more of MoO₂Cl₂ and MoO₂Br₂ and one or more chalcogenide precursor of formula (i) R₁XR₂ and/or formula (ii) R₁XXR₂, where X=S, Se or Te, and R₁ and R₂ are each independently one of hydrogen, an unsubstituted linear C₁-C₆ alkyl group, a linear C₁-C₆ alkyl group substituted with one or more halogen, a linear C₁-C₆ alkyl group substituted with an amino group, an unsubstituted branched C₃-C₆ alkyl group, a branched C₃-C₆ alkyl group substituted with one or more halogen, a branched C₃-C₆ alkyl group substituted with an amino group, an unsubstituted amine, a substituted amine, and —Si(CH₃)₃.

In one aspect of this embodiment, the ALD deposition is performed under conditions that yield “self-limiting-layer-synthesis” and/or “self-limiting-layer-synthesis-like” conditions to grow 2D MoS₂, 2D MoSe₂ or 2D MoTe₂ layers.

In another aspect of this embodiment, the ALD deposition yields “self-limiting-layer-synthesis” or “self-limiting-layer-synthesis like” conditions for the deposited MoX₂ films which exhibit superior quality crystalline order in the grown semiconducting films with increased electron and/or hole mobilities beneficial in semiconductors due to reduced vacancy sites in the MoX₂ lattice, especially chalcogen vacancy sites.

In another aspect of this embodiment, the ALD operating conditions are “balanced” to produce “self-limiting-layer-synthesis” or “self-limiting-layer-synthesis-like” depositions. Namely, a balance of the chlorine atoms in the MoO₂Cl₂ precursor and the chlorides of the chalcogenide precursor's ligands after ligand exchange reaction. In this aspect of the disclosed and claimed subject matter these chlorine atoms not only add an etch component but also behave as mild Cl-dopants in the deposited film, helping to improve the electrical properties of the semiconducting MoX₂ film.

In another aspect of this embodiment, the ALD deposition temperature window ranges from about 100° C. to about 650° C., and the pressures range from about 0.1 to about 100 Torr. In a further aspect, the deposition temperatures and pressures are tuned to the chalcogenide precursor chosen.

In another aspect of this embodiment, the substrate surface is pretreated either with a recipe of one or more chemicals and/or by plasma process preparation prior to deposition of the MoX₂ film described herein.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity's sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates ALD growth of MoSe₂ using MoO₂Cl₂+iPr₂Se at 450° C. in an embodiment (Example 1) of the disclosed and claimed subject matter;

FIG. 2 illustrates that the disclosed and claimed ALD processes exhibit flat deposition rate across the ALD deposition window;

FIG. 3 illustrates that the disclosed and claimed ALD processes exhibit self-limiting-layer-synthesis behavior in its growth curves.

FIG. 4 illustrates the Raman spectroscopy of MoSe₂ films made according to the disclosed and claimed ALD processes;

FIG. 5 illustrates the Raman FWHM (Full Width at Half Maximum of the Raman peak) vs. deposition temperature across the growth curve (left image shows the A_{1g} FWHM versus ALD cycles at two temperatures and right image shows the XPS Se/Mo ratio versus cycles at two temperatures);

FIG. 6 illustrates the DEDS saturation curve, showing saturation at about 3 s DEDS pulse length of MoS₂ using MoO₂Cl₂+Et₂S₂ in an embodiment (Example 2) of the disclosed and claimed subject matter;

FIG. 7 illustrates the saturation curve for Example 2 showing saturation at about 3 s MoO₂Cl₂ pulse length;

FIG. 8 illustrates the temperature window for Example 2 which produces relatively constant thickness for saturated processes vs. temperature;

FIG. 9 illustrates that the ALD MoO₂Cl₂+Et₂S₂ growth curve of Exhibit 2 exhibits a soft saturation behavior which is self-limiting-layer-synthesis-like behavior;

FIG. 10 illustrates a plot of the Raman A1g and E2g FWHM for the samples in Example 2 vs ALD cycles with full spectra shown at 50 and 500 cycles, illustrating the improvements in FWHM at an optimal cycle count;

FIG. 11 illustrates an SEM showing fin-free MoS₂ growth; and

FIG. 12 illustrates a TEM showing fin-free MoS₂ growth.

### DEFINITIONS

Unless otherwise stated, the following terms used in the specification and claims shall have the following meanings for this application.

In this application, the use of the singular includes the plural, and the words “a,” “an” and “the” mean “at least one” unless specifically stated otherwise. Furthermore, the use of the term “including,” as well as other forms such as “includes” and “included,” is not limiting. Also, terms such as “element” or “component” encompass both elements or components including one unit and elements or components that include more than one unit, unless specifically stated otherwise. As used herein, the conjunction “and” is intended to be inclusive and the conjunction “or” is not intended to be exclusive, unless otherwise indicated. For example, the phrase “or, alternatively” is intended to be exclusive. As used herein, the term “and/or” refers to any combination of the foregoing elements including using a single element.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

As used herein, “C_{x-y}” (where x and y are each integers) designates the number of carbon atoms in a chain. For example, C₁₋₆ alkyl refers to an alkyl chain having a chain of between 1 and 6 carbons (e.g., methyl, ethyl, propyl, butyl, pentyl and hexyl). Unless specifically stated otherwise, the chain can be linear or branched.

Unless otherwise indicated, “alkyl” refers to hydrocarbon groups which can be linear, branched (e.g., methyl, ethyl, propyl, isopropyl, tert-butyl and the like), cyclic (e.g., cyclohexyl, cyclopropyl, cyclopentyl and the like) or multicyclic (e.g., norbornyl, adamantly and the like). Suitable acyclic groups can be methyl, ethyl, n- or iso-propyl, n-, iso, or tert-butyl, linear or branched pentyl, hexyl, heptyl, octyl, decyl, dodecyl, tetradecyl and hexadecyl. Unless otherwise stated, alkyl refers to 1-10 carbon atom moieties. The cyclic alkyl groups may be mono cyclic or polycyclic. Suitable examples of mono-cyclic alkyl groups include substituted cyclopentyl, cyclohexyl, and cycloheptyl groups. As mentioned herein the cyclic alkyl groups may have any of the acyclic alkyl groups as substituent. These alkyl moieties may be substituted or unsubstituted.

“Halogenated alkyl” refers to a linear, cyclic or branched saturated alkyl group as defined above in which one or more of the hydrogens has been replaced by a halogen (e.g., F, Cl, Br and I). Thus, for example, a fluorinated alkyl (a.k.a. “fluoroalkyl”) refers to a linear, cyclic or branched saturated alkyl group as defined above in which one or more of the hydrogens has been replaced by fluorine (e.g., trifluoromethyl, pefluoroethyl, 2,2,2-trifluoroethyl, prefluoroisopropyl, perfluorocyclohexyl and the like). Such haloalkyl moieties (e.g., fluoroalkyl moieties), if not perhalogenated/multihalogentated, may be unsubstituted or further substituted.

“Alkoxy” (a.k.a. “alkyloxy”) refers to an alkyl group as defined above which is attached through an oxy (—O—) moiety (e.g., methoxy, ethoxy, propoxy, butoxy, 1,2-isopropoxy, cyclopentyloxy, cyclohexyloxy and the like). These alkoxy moieties may be substituted or unsubstituted.

“Alkyl carbonyl” refers to an alkyl group as defined above which is attached through a carbonyl group (—C(═O—)) moiety (e.g., methylcarbonyl, ethylcarbonyl, propylcarbonyl, buttylcarbonyl, cyclopentylcarbonyl and the like). These alkyl carbonyl moieties may be substituted or unsubstituted.

“Halo” or “halide” refers to a halogen (e.g., F, Cl, Br and I).

“Hydroxy” (a.k.a. “hydroxyl”) refers to an —OH group.

The term “aryl” denotes an aromatic cyclic functional group having from 4 to 10 carbon atoms, from 5 to 10 carbon atoms, or from 6 to 10 carbon atoms. Exemplary aryl groups include, but are not limited to, phenyl, 1-phenylethyl (Ph(Me)CH—), 1-phenyl-1-methyl-ethyl (Ph(Me)₂C—), benzyl, chlorobenzyl, tolyl, o-xylyl, 1,2,3-triazolyl, pyrrolyl and furanyl.

Unless otherwise indicated, the term “substituted” when referring to an alkyl, alkoxy, fluorinated alkyl and the like refers to one of these moieties which also contains one or more substituents including, but not limited, to the following substituents: alkyl, substituted alkyl, unsubstituted aryl, substituted aryl, alkyloxy, alkylaryl, haloalkyl, halide, hydroxy, amino and amino alkyl. Similarly, the term “unsubstituted” refers to these same moieties where no substituents apart from hydrogen are present.

For purposes of this invention and the claims hereto, the numbering scheme for the Periodic Table Groups is according to the IUPAC Periodic Table of Elements.

The term “and/or” as used in a phrase such as “A and/or B” herein is intended to include “A and B,” “A or B,” “A” and “B.”

The terms “substituent,” “radical,” “group” and “moiety” may be used interchangeably.

As used herein, the terms “metal-containing complex” (or more simply, “complex”) and “precursor” are used interchangeably and refer to metal-containing molecule or compound which can be used to prepare a metal-containing film by a vapor deposition process such as, for example, ALD or CVD. The metal-containing complex may be deposited on, adsorbed to, decomposed on, delivered to, and/or passed over a substrate or surface thereof, as to form a metal-containing film. In one or more embodiments, the metal-containing complexes disclosed herein are metal oxyhalide complexes, particularly molybdenum oxychloride complexes.

As used herein, the term “ALD” denotes to a self-limiting deposition process, but not limited to, the following processes: a) each reactant including vapors comprising MoO₂Cl₂ and chalcogenide precursors is introduced sequentially into a reactor such as a single wafer ALD reactor, semi-batch ALD reactor, or batch furnace ALD reactor; b) each reactant including vapors comprising MoO₂Cl₂ and chalcogenide precursors is exposed to a substrate by moving or rotating the substrate to different sections of the reactor and each section is separated by inert gas curtain, i.e., spatial ALD reactor or roll to roll ALD reactor.

As used herein, the term “metal-containing film” includes not only an elemental metal film as more fully defined below, but also a film which includes a metal along with one or more elements, for example a metal oxide film, metal nitride film, metal silicide film, a metal carbide film, a metal sulfide film, a metal selenide film, a metal telluride film, and the like.

As used herein, the term “vapor deposition process” is used to refer to any type of vapor deposition technique, including but not limited to, CVD and ALD. In various embodiments, CVD may take the form of conventional (i.e., continuous flow) CVD, liquid injection CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al. J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds. The Royal Society of Chemistry: Cambridge, 2009; Chapter 1, pp. 1-36.

As used herein, the term “feature” refers to an opening in a substrate which may be defined by one or more sidewalls, a bottom surface, and upper corners. In various aspects, the feature may be a via, a trench, contact, dual damascene, etc.

As used herein, the terms “selective growth,” “selectively grown” and “selectively grows” may be used synonymously and refer to film growth on at least a portion of a first substrate and substantially no film growth on a remaining portion of the first substrate as well as more film growth on at least a portion of the first substrate compared to film growth on a remaining portion of the first substrate. For example, selective growth may include growth of a film on a lower portion of a feature while less film growth or no film growth may occur in an upper portion of that feature or outside that feature. With respect to more than one substrate, the terms “selective growth” “selectively grown” and “selectively grows” also encompass film growth on a first substrate and substantially no film growth on a second substrate (or a third substrate, or fourth substrate or a fifth substrate, etc.) as well as more film growth on the first substrate than on the second substrate (or a third substrate, or fourth substrate or a fifth substrate, etc.).

The MoO₂Cl₂ and/or MoO₂Br₂ and one or more chalcogenide precursors according to the disclosed and claimed subject matter are preferably substantially free of water. As used herein, the term “substantially free” as it relates to water, means less than 5000 ppm (by weight) measured by proton NMR or Karl Fischer titration, preferably less than 3000 ppm measured by proton NMR or Karl Fischer titration, and more preferably less than 1000 ppm measured by proton NMR or Karl Fischer titration, and most preferably 100 ppm measured by proton NMR or Karl Fischer titration. The MoO₂Cl₂ and one or more chalcogenide precursor are also preferably substantially free of metal ions or metals such as, Li⁺ (Li), Na⁺ (Na), K⁺ (K), Mg²⁺ (Mg), Ca²⁺ (Ca) Al³⁺ (Al), Fe²⁺ (Fe), Fe³⁺ (Fe), Ni²⁺ (Fe), Cr³⁺ (Cr), titanium (Ti), vanadium (V), manganese (Mn), cobalt (Co), nickel (Ni), copper (Cu) or zinc (Zn). Those metal ions or metals are potentially from starting materials/reactor employed to synthesize the MoO₂Cl₂ and one or more chalcogenide precursor. As used herein, the term “substantially free” as it relates to Li, Na, K, Mg, Ca, Al, Fe, Ni, Cr, Ti, V, Mn, Co, Ni, Cu or Zn means less than 5 ppm (by weight), preferably less than 3 ppm, and more preferably less than 1 ppm, and most preferably 0.1 ppm as measured by ICP-MS. In addition, the MoO₂Cl₂ and/or MoO₂Br₂ and one or more chalcogenide precursor are preferably substantially free of organic impurities which are from either starting materials employed during synthesis or by-products generated during synthesis. Examples include, but not limited to, alkanes, alkenes, alkynes, dienes, ethers, esters, acetates, amines, ketones, amides, aromatic compounds. As used herein, the term “free of” organic impurities, means 1000 ppm or less as measured by GC, preferably 500 ppm or less (by weight) as measured by GC, most preferably 100 ppm or less (by weight) as measured by GC or other analytical method for assay. Importantly the MoO₂Cl₂ and one or more chalcogenide precursor preferably have purity of 98 wt. % or higher, more preferably 99 wt. % or higher as measured by GC when used as precursor to deposit the Mo-containing films.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

As set forth above, the disclosed subject matter relates to ALD deposition processes using MoO₂Cl₂ and/or MoO₂Br₂ and one or more chalcogenide precursor of formula (i) R₁XR₂ and/or formula (ii) R₁XXR₂, where X=S, Se or Te, and R₁ and R₂ are each independently one of hydrogen, an unsubstituted linear C₁-C₆ alkyl group, a linear C₁-C₆ alkyl group substituted with one or more halogen, a linear C₁-C₆ alkyl group substituted with an amino group, an unsubstituted branched C₃-C₆ alkyl group, a branched C₃-C₆ alkyl group substituted with one or more halogen, a branched C₃-C₆ alkyl group substituted with an amino group, an unsubstituted amine, a substituted amine, and —Si(CH₃)₃. In one embodiment, R₁ and R₂ are each independently one of hydrogen, methyl, ethyl, n-propyl, iso-propyl, n-butyl, sec-butyl, iso-butyl and tert-butyl. In one embodiment, the process includes using MoO₂Cl₂. In one embodiment, the process includes using MoO₂Br₂. Specific aspects of the disclosed and claimed ALD processes are described below.

In one embodiment, the disclosed and claimed subject matter relates to a method for depositing Mo-containing films using MoO₂Cl₂ and one or more chalcogenide precursor of formula (i) R₁XR₂ and/or formula (ii) R₁XXR₂, where X=S, Se or Te, and R₁ and R₂ are each independently one of hydrogen, an unsubstituted linear C₁-C₆ alkyl group, a linear C₁-C₆ alkyl group substituted with one or more halogen, a linear C₁-C₆ alkyl group substituted with an amino group, an unsubstituted branched C₃-C₆ alkyl group, a branched C₃-C₆ alkyl group substituted with one or more halogen, a branched C₃-C₆ alkyl group substituted with an amino group, an unsubstituted amine, a substituted amine, and —Si(CH₃)₃. In one aspect of this embodiment, R₁ and R₂ are each independently one of hydrogen, methyl, ethyl, n-propyl, iso-propyl, n-butyl, sec-butyl, iso-butyl and tert-butyl. The method includes (i) contacting a substrate with MoO₂Cl₂ vapor in a deposition reactor, (ii) purging any unreacted MoO₂Cl₂ with inert gas, (iii) contacting the substrate with a chalcogenide precursor of the above formulae in a deposition reactor and (iv) optionally purging of any unreacted chalcogenide precursor with inert gas. In a further aspect of this embodiment, the method consists essentially of steps (i), (ii), (iii) and (iv). In a further aspect of this embodiment, the method consists of steps (i), (ii), (iii) and (iv).

In one embodiment, the disclosed and claimed subject matter relates to a method for depositing Mo-containing films using MoO₂Cl₂ and one or more chalcogenide precursor of formula (i) R₁XR₂ and/or formula (ii) R₁XXR₂, where X=S, Se or Te, and R₁ and R₂ are each independently one of hydrogen, an unsubstituted linear C₁-C₆ alkyl group, a linear C₁-C₆ alkyl group substituted with one or more halogen, a linear C₁-C₆ alkyl group substituted with an amino group, an unsubstituted branched C₃-C₆ alkyl group, a branched C₃-C₆ alkyl group substituted with one or more halogen, a branched C₃-C₆ alkyl group substituted with an amino group, an unsubstituted amine, a substituted amine, and —Si(CH₃)₃. In one aspect of this embodiment, R₁ and R₂ are each independently one of hydrogen, methyl, ethyl, n-propyl, iso-propyl, n-butyl, sec-butyl, iso-butyl and tert-butyl. The method includes (i) contacting a substrate with MoO₂Cl₂ vapor in a deposition reactor, (ii) purging any unreacted MoO₂Cl₂ with inert gas, (iii) contacting the substrate with a chalcogenide precursor of the above formulae in a deposition reactor, (iv) optionally purging of any unreacted chalcogenide precursor with inert gas, and (v) treating the substrate with H₂S gas and/or an H₂S plasma to remove residual oxygen. In a further aspect of this embodiment, the method consists essentially of steps (i), (ii), (iii), (iv) and (v). In a further aspect of this embodiment, the method consists of steps (i), (ii), (iii), (iv) and (v).

In one embodiment, the disclosed and claimed subject matter relates to a method for depositing Mo-containing films using MoO₂Br₂ and one or more chalcogenide precursor of formula (i) R₁XR₂ and/or formula (ii) R₁XXR₂, where X=S, Se or Te, and R₁ and R₂ are each independently one of hydrogen, an unsubstituted linear C₁-C₆ alkyl group, a linear C₁-C₆ alkyl group substituted with one or more halogen, a linear C₁-C₆ alkyl group substituted with an amino group, an unsubstituted branched C₃-C₆ alkyl group, a branched C₃-C₆ alkyl group substituted with one or more halogen, a branched C₃-C₆ alkyl group substituted with an amino group, an unsubstituted amine, a substituted amine, and —Si(CH₃)₃. In one aspect of this embodiment, R₁ and R₂ are each independently one of hydrogen, methyl, ethyl, n-propyl, iso-propyl, n-butyl, sec-butyl, iso-butyl and tert-butyl. The method includes (i) contacting a substrate with MoO₂Br₂ vapor in a deposition reactor, (ii) purging any unreacted MoO₂Cl₂ with inert gas, (iii) contacting the substrate with a chalcogenide precursor of the above formulae in a deposition reactor and (iv) optionally purging of any unreacted chalcogenide precursor with inert gas. In a further aspect of this embodiment, the method consists essentially of steps (i), (ii), (iii) and (iv). In a further aspect of this embodiment, the method consists of steps (i), (ii), (iii) and (iv).

In one embodiment, the disclosed and claimed subject matter relates to a method for depositing Mo-containing films using MoO₂Br₂ and one or more chalcogenide precursor of formula (i) R₁XR₂ and/or formula (ii) R₁XXR₂, where X=S, Se or Te, and R₁ and R₂ are each independently one of hydrogen, an unsubstituted linear C₁-C₆ alkyl group, a linear C₁-C₆ alkyl group substituted with one or more halogen, a linear C₁-C₆ alkyl group substituted with an amino group, an unsubstituted branched C₃-C₆ alkyl group, a branched C₃-C₆ alkyl group substituted with one or more halogen, a branched C₃-C₆ alkyl group substituted with an amino group, an unsubstituted amine, a substituted amine, and —Si(CH₃)₃. In one aspect of this embodiment, R₁ and R₂ are each independently one of hydrogen, methyl, ethyl, n-propyl, iso-propyl, n-butyl, sec-butyl, iso-butyl and tert-butyl. The method includes (i) contacting a substrate with MoO₂Br₂ vapor in a deposition reactor, (ii) purging any unreacted MoO₂Br₂ with inert gas, (iii) contacting the substrate with a chalcogenide precursor of the above formulae in a deposition reactor, (iv) optionally purging of any unreacted chalcogenide precursor with inert gas, and (v) treating the substrate with H₂S gas and/or an H₂S plasma to remove residual oxygen. In a further aspect of this embodiment, the method consists essentially of steps (i), (ii), (iii), (iv) and (v). In a further aspect of this embodiment, the method consists of steps (i), (ii), (iii), (iv) and (v).

In one embodiment, the substrate surface can be pretreated either with a recipe of one or more chemicals and/or by plasma process preparation prior to the MoX₂ deposition.

Delivery of MoO₂Cl₂ and/or MoO₂Br₂

As noted above, step (i) of the disclosed and claimed method includes contacting a substrate with one or more of MoO₂Cl₂ and MoO₂Br₂·vapor. MoO₂Cl₂ and MoO₂Br₂ are highly suitable for use as volatile precursor for ALD and/or plasma enhanced atomic layer deposition (PEALD). As used herein, the term “atomic layer deposition process” refers to a self-limiting (i.e., film thickness saturates asymptotically after a certain number of cycles), sequential surface chemistry that deposits films of materials onto substrates of varying compositions.

Those skilled in the art will recognize that when delivering the MoO₂Cl₂ and/or MoO₂Br₂ precursor it is possible to adjust and balance factors such as MoO₂Cl₂ and/or MoO₂Br₂ precursor pulse time, MoO₂Cl₂ and/or MoO₂Br₂ vapor pressure, and MoO₂Cl₂ and/or MoO₂Br₂ carrier flow rate determine the arrival rate of MoO₂Cl₂ and/or MoO₂Br₂ molecules entering the chamber, and the total dose of MoO₂Cl₂ and/or MoO₂Br₂ molecules entering the chamber. For example, increasing the vapor pressure by a factor of two while decreasing the pulse time by a factor of two keeps the MoO₂Cl₂ and/or MoO₂Br₂ dose constant while still varying the arrival rate of MoO₂Cl₂ and/or MoO₂Br₂ molecules. The covariation of these three variables determines the total MoO₂Cl₂ and/or MoO₂Br₂ dose into the chamber, the flux rate of the MoO₂Cl₂ and/or MoO₂Br₂ molecules into the chamber, the time allowed for each MoO₂Cl₂ and/or MoO₂Br₂ molecule to vaporize in the MoO₂Cl₂ and/or MoO₂Br₂ ampule, and any turbulent flow of the carrier gas in the MoO₂Cl₂ and/or MoO₂Br₂ ampule.

In another embodiment, the MoO₂Cl₂ and/or MoO₂Br₂ vapor pulse time is from about 0.1 seconds to about 25 seconds. In another embodiment, the MoO₂Cl₂ and/or MoO₂Br₂ vapor pulse time is from about 0.3 seconds to about 18 seconds. In another embodiment, the MoO₂Cl₂ and/or MoO₂Br₂ vapor pulse time is about 1 second. In another embodiment, the MoO₂Cl₂ and/or MoO₂Br₂ vapor pulse time is about 2 seconds. In another embodiment, the MoO₂Cl₂ and/or MoO₂Br₂ vapor pulse time is about 3 seconds. In another embodiment, the MoO₂Cl₂ and/or MoO₂Br₂ vapor pulse time is about 4 seconds. In another embodiment, the MoO₂Cl₂ and/or MoO₂Br₂ vapor pulse time is about 5 seconds. In another embodiment, the MoO₂Cl₂ and/or MoO₂Br₂ vapor pulse time is about 6 seconds. In another embodiment, the MoO₂Cl₂ and/or MoO₂Br₂ vapor pulse time is about 7 seconds. In another embodiment, the MoO₂Cl₂ and/or MoO₂Br₂ vapor pulse time is about 8 seconds. In another embodiment, the MoO₂Cl₂ and/or MoO₂Br₂ vapor pulse time is about 10 seconds. In another embodiment, the MoO₂Cl₂ and/or MoO₂Br₂ vapor pulse time is about 12 seconds. In another embodiment, the MoO₂Cl₂ and/or MoO₂Br₂ vapor pulse time is about 15 seconds.

The MoO₂Cl₂ and/or MoO₂Br₂ ampule temperature is used to control the MoO₂Cl₂ and/or MoO₂Br₂ vapor pressure. In another embodiment, the MoO₂Cl₂ and/or MoO₂Br₂ ampule temperature is from about 55° C. to about 300° C. In another embodiment, the MoO₂Cl₂ and/or MoO₂Br₂ ampule temperature is from about 60° C. to about 160° C. In another embodiment, the MoO₂Cl₂ and/or MoO₂Br₂ ampule temperature is about 65° C. In another embodiment, the MoO₂Cl₂ and/or MoO₂Br₂ ampule temperature is about 75° C. In another embodiment, the MoO₂Cl₂ and/or MoO₂Br₂ ampule temperature is about 85° C. In another embodiment, the MoO₂Cl₂ and/or MoO₂Br₂ ampule temperature is about 90° C. In another embodiment, the MoO₂Cl₂ and/or MoO₂Br₂ ampule temperature is about 115° C. In another embodiment, the MoO₂Cl₂ and/or MoO₂Br₂ ampule temperature is about 130° C. In another embodiment, the MoO₂Cl₂ and/or MoO₂Br₂ ampule temperature is about 150° C.

In another embodiment, the MoO₂Cl₂ and/or MoO₂Br₂ carrier gas flow is from about 5 sccm to about 3000 sccm. In another embodiment, the MoO₂Cl₂ and/or MoO₂Br₂ carrier gas flow is from about 30 sccm to about 1000 sccm. In another embodiment, the MoO₂Cl₂ and/or MoO₂Br₂ carrier gas flow is about 50 sccm. In another embodiment, the MoO₂Cl₂ and/or MoO₂Br₂ carrier gas flow is about 75 sccm. In another embodiment, the MoO₂Cl₂ and/or MoO₂Br₂ carrier gas flow is about 100 sccm. In another embodiment, the MoO₂Cl₂ and/or MoO₂Br₂ carrier gas flow is about 150 sccm. In another embodiment, the MoO₂Cl₂ and/or MoO₂Br₂ carrier gas flow is about 200 sccm. In another embodiment, the MoO₂Cl₂ and/or MoO₂Br₂ carrier gas flow is about 350 sccm. In another embodiment, the MoO₂Cl₂ and/or MoO₂Br₂ carrier gas flow is about 500 sccm. In another embodiment, the MoO₂Cl₂ and/or MoO₂Br₂ carrier gas flow is about 650 sccm.

In one embodiment, the MoO₂Cl₂ and/or MoO₂Br₂ vapor is separated from other precursor materials prior to and/or during the introduction to the reactor. This process avoids pre-reaction of the metal precursor with any other materials.

In another embodiment, the MoO₂Cl₂ and/or MoO₂Br₂ vapor is alternatively exposed to the substrate with other reactants (e.g., ammonia vapor, and/or other precursors or reagents). This process enables film growth to proceed by self-limiting control of the surface reactions, the pulse length of each precursor or reagent and the deposition temperature. It should be noted, however, that film growth ceases once the surface of the substrate is saturated with MoO₂Cl₂ and/or MoO₂Br₂ vapor.

In another embodiment, a flow of argon and/or other gas is employed as a carrier gas to help deliver the vapor of the MoO₂Cl₂ and/or MoO₂Br₂ to the reaction reactor during the precursor pulsing.

MoO₂Cl₂ and/or MoO₂Br₂ Purging Step

As noted above, step (ii) of the disclosed and claimed method includes purging any unreacted MoO₂Cl₂ and/or MoO₂Br₂ with inert gas. Purging with an inert gas removes unabsorbed excess complex from the process reactor.

In one embodiment, the purge time varies from about 1 second to about 90 seconds. In one embodiment, the purge time varies from about 10 seconds to about 90 seconds. In one embodiment, the purge time varies from about 15 seconds to about 60 seconds. In another embodiment, the purge time is about 20 seconds. In another embodiment, the purge time is about 30 seconds. In another embodiment, the purge time is about 40 seconds. In another embodiment, the purge time is about 60 seconds.

In one embodiment, the purge gas includes argon. In another embodiment, the purge gas includes nitrogen.

### Chalcogenide Precursor

As noted above, step (iii) of the disclosed and claimed method includes contacting the substrate with a chalcogenide precursor in the deposition reactor for a period of time. In one embodiment, the chalcogenide precursor has formula (i) R₁XR₂ and/or formula (ii) R₁XXR₂, where X=S, Se or Te, and R₁ and R₂ are each independently one of an unsubstituted linear C₁-C₆ alkyl group, a linear C₁-C₆ alkyl group substituted with one or more halogen, a linear C₁-C₆ alkyl group substituted with an amino group, an unsubstituted branched C₃-C₆ alkyl group, a branched C₃-C₆ alkyl group substituted with one or more halogen, a branched C₃-C₆ alkyl group substituted with an amino group, an unsubstituted amine, a substituted amine, and —Si(CH₃)₃. In one embodiment, R₁ and R₂ are each independently one of hydrogen, methyl, ethyl, n-propyl, iso-propyl, n-butyl, sec-butyl, iso-butyl and tert-butyl. Specific aspects of the disclosed and claimed ALD processes are described below.

In one aspect of this embodiment, the chalcogenide precursor has formula (i) R₁XR₂ where X=S, Se or Te, and R₁ and R₂ are each independently one of an unsubstituted linear C₁-C₆ alkyl group, a linear C₁-C₆ alkyl group substituted with one or more halogen, a linear C₁-C₆ alkyl group substituted with an amino group, an unsubstituted branched C₃-C₆ alkyl group, a branched C₃-C₆ alkyl group substituted with one or more halogen, a branched C₃-C₆ alkyl group substituted with an amino group, an unsubstituted amine, a substituted amine, and —Si(CH₃)₃. In further aspect, R₁ and R₂ are each independently one of hydrogen, methyl, ethyl, n-propyl, iso-propyl, n-butyl, sec-butyl, iso-butyl and tert-butyl.

In another aspect of this embodiment, the chalcogenide precursor has formula (ii) R₁XXR₂, where X=S, Se or Te, and R₁ and R₂ are each independently one of an unsubstituted linear C₁-C₆ alkyl group, a linear C₁-C₆ alkyl group substituted with one or more halogen, a linear C₁-C₆ alkyl group substituted with an amino group, an unsubstituted branched C₃-C₆ alkyl group, a branched C₃-C₆alkyl group substituted with one or more halogen, a branched C₃-C₆ alkyl group substituted with an amino group, an unsubstituted amine, a substituted amine, and —Si(CH₃)₃. In a further aspect, one embodiment, R₁ and R₂ are each independently one of hydrogen, methyl, ethyl, n-propyl, iso-propyl, n-butyl, sec-butyl, iso-butyl and tert-butyl.

In one aspect of the above embodiments, X is preferably S. In another aspect of the above embodiments, X is preferably Se. In another aspect of the above embodiments, X is preferably Te.

In one aspect of the above embodiments, one or both of R₁ and R₂ is preferably hydrogen. In one aspect of the above embodiments, one or both of R₁ and R₂ is preferably methyl. In one aspect of the above embodiments, one or both of R₁ and R₂ is preferably ethyl. In one aspect of the above embodiments, one or both of R₁ and R₂ is preferably n-propyl. In one aspect of the above embodiments, one or both of R₁ and R₂ is preferably iso-propyl. In one aspect of the above embodiments, one or both of R₁ and R₂ is preferably n-butyl. In one aspect of the above embodiments, one or both of R₁ and R₂ is preferably iso-butyl. In one aspect of the above embodiments, one or both of R₁ and R₂ is preferably tert-butyl.

Those skilled in the art will recognize that when delivering the chalcogenide precursor, it is possible to adjust and balance factors such as chalcogenide precursor pulse time, chalcogenide precursor vapor pressure, and chalcogenide precursor carrier flow rate determine the arrival rate of chalcogenide precursor molecules entering the chamber, and the total dose of chalcogenide precursor molecules into the chamber. For example, increasing the vapor pressure by a factor of two while decreasing the pulse time by a factor of two keeps the chalcogenide precursor dose constant while still varying the arrival rate of chalcogenide precursor molecules. The covariation of these three variables determines the total chalcogenide precursor dose into the chamber, the flux rate of the chalcogenide precursor molecules into the chamber, the time allowed for each chalcogenide precursor molecule to vaporize in the chalcogenide precursor ampule, and any turbulent flow of the carrier gas in the chalcogenide precursor ampule.

In one embodiment, the chalcogenide precursor pulse time varies from about 0.5 seconds to about 25 seconds. In one embodiment, the chalcogenide precursor pulse time varies from about 1 second to about 15 seconds. In one embodiment, the chalcogenide precursor pulse time is about 1 second. In one embodiment, the chalcogenide precursor pulse time is about 5 seconds. In one embodiment, the chalcogenide precursor pulse time is about 10 seconds. In one embodiment, the chalcogenide precursor pulse time is about 15 seconds.

The precursor vapor pressure is controlled by the choice of chalcogenide precursor molecular, and the temperature of the ampule if the precursor is a liquid. In one embodiment, the chalcogenide precursor vapor pressure varies from about 0.3 Torr to about 15,000 Torr. In one embodiment, the chalcogenide precursor vapor pressure is about 2 Torr. In one embodiment, the chalcogenide precursor vapor pressure is about 10 Torr. In one embodiment, the chalcogenide precursor vapor pressure is about 30 Torr. In one embodiment, the chalcogenide precursor vapor pressure is about 90 Torr. In one embodiment, the chalcogenide precursor vapor pressure is about 200 Torr. In one embodiment, the chalcogenide precursor is a gas delivered to the chamber (by definition, a gas has vapor pressure ≥760 Torr), such as H₂S with vapor pressure of about 13,000 Torr at 70° C.

In one embodiment, the chalcogenide precursor carrier gas flow varies from about 0 sccm (vapor draw) to about 3000 sccm. In one embodiment, the chalcogenide precursor carrier gas flow is about 5 sccm. In one embodiment, the chalcogenide precursor carrier gas flow is about 50 sccm. In one embodiment, the chalcogenide precursor carrier gas flow is about 100 sccm. In one embodiment, the chalcogenide precursor carrier gas flow is about 250 sccm. In one embodiment, the chalcogenide precursor carrier gas flow is about 500 sccm. In one embodiment, the chalcogenide precursor carrier gas flow is about 750 sccm. In one embodiment, the chalcogenide precursor carrier gas flow is about 1000 sccm. In one embodiment, the chalcogenide precursor carrier gas flow is about 1250 sccm. In one embodiment, the chalcogenide precursor carrier gas flow is about 1500 sccm. In one embodiment, the chalcogenide precursor carrier gas flow is about 1750 sccm. In one embodiment, the chalcogenide precursor carrier gas flow is about 2000 sccm.

### Preferred Precursor Sets

The ALD processes of the disclosed and claimed subject matter can utilize any precursor sets combining MoO₂Cl₂ and/or MoO₂Br₂ and one or more of the above chalcogenide precursors as follows:

In one embodiment, the precursor set includes MoO₂Cl₂ and iBu₂S. In one embodiment, the precursor set includes MoO₂Br₂ and iBu₂S.

In one embodiment, the precursor set includes MoO₂Cl₂ and iPr₂S. In one embodiment, the precursor set includes MoO₂Br₂ and iPr₂S.

In one embodiment, the precursor set includes MoO₂Cl₂ and iPr₂Se. In one embodiment, the precursor set includes MoO₂Br₂ and iPr₂Se.

In one embodiment, the precursor set includes MoO₂Cl₂ and Et₂S₂. In one embodiment, the precursor set includes MoO₂Br₂ and Et₂S₂.

In one embodiment, the precursor set includes MoO₂Cl₂ and Et₂Se. In one embodiment, the precursor set includes MoO₂Br₂ and Et₂Se.

In one embodiment, the precursor set includes MoO₂Cl₂ and tBuSH. In one embodiment, the precursor set includes MoO₂Br₂ and tBuSH.

In one embodiment, the precursor set includes MoO₂Cl₂ and H₂Se. In one embodiment, the precursor set includes MoO₂Br₂ and H₂Se.

In one embodiment, the precursor set includes MoO₂Cl₂ and H₂S. In one embodiment, the precursor set includes MoO₂Br₂ and H₂S.

In one embodiment, the precursor set includes MoO₂Cl₂ and H₂Te. In one embodiment, the precursor set includes MoO₂Br₂ and H₂Te.

In one embodiment, the precursor set includes MoO₂Cl₂ and Et₂Te. In one embodiment, the precursor set includes MoO₂Br₂ and Et₂Te.

In one embodiment, the precursor set includes MoO₂Cl₂ and iPr₂Te. In one embodiment, the precursor set includes MoO₂Br₂ and iPr₂Te.

### Optional Chalcogenide Precursor Purging Step

As noted above, step (iv) of the disclosed and claimed method includes optionally purging of any unreacted chalcogenide precursor with inert gas. Purging with an inert gas removes any remaining chalcogenide precursor from the process reactor. In one embodiment, the purge gas includes argon. In another embodiment, the purge gas includes nitrogen. As those skilled in the art will recognize, in many instances, if not in most instances, the disclosed and claimed process will include the step of purging the unreacted chalcogenide precursor.

In one embodiment, for example, the optional chalcogenide precursor purge time varies from about 4 seconds to about 90 seconds. In one embodiment, for example, the optional chalcogenide precursor purge time varies from about 15 seconds to about 60 seconds. In another embodiment, the optional chalcogenide precursor purge time is about 30 seconds. In another embodiment, the optional chalcogenide precursor purge time is about 60 seconds. In another embodiment, the optional chalcogenide precursor purge time is about 90 seconds.

Additional Gas and/or Plasma Treatment

As noted above, step (v) of the disclosed and claimed method includes substrate treatment with H₂S gas and/or H₂S plasma to remove residual oxygen from the film formed during the previous steps.

In one embodiment, the use of plasma constitutes a direct plasma-generated process in which plasma is directly generated in the reactor. In another embodiment, the use of plasma constitutes a remote plasma-generated process in which plasma is generated outside of the reactor and supplied into the reactor.

### Operating Conditions

As noted above, the disclosed and claimed molybdenum deposition processes can be effectively conducted under very favorable ALD conditions to provide highly conformal Mo-containing films.

### Temperature

In one embodiment a substrate (e.g., an aluminum oxide (Al₂O₃), aluminum nitride (AlN), silicon oxide (SiO₂), silicon oxynitride, silicon nitride (Si₃N₄), zirconium oxide (ZrO₂), and hafnium oxide (HfO₂)) is heated on a heater stage in a reaction reactor that is exposed to a selected precursor set initially to allow the complex to chemically adsorb onto the surface of the substrate. In one embodiment, the substrate temperature is from about 100° C. to about 650° C. In one embodiment, the substrate temperature is from about 200° C. to about 650° C. In a further aspect of this embodiment, the substrate temperature is from about 250° C. to about 600° C. In a further aspect of this embodiment, the substrate temperature is from about 300° C. to about 550° C. In a further aspect of this embodiment, the substrate temperature is from about 450° C. to about 525° C.

In a further aspect of this embodiment, the substrate temperature is about 150° C. In a further aspect of this embodiment, the substrate temperature is about 200° C. In a further aspect of this embodiment, the substrate temperature is about 250° C. In a further aspect of this embodiment, the substrate temperature is about 300° C. In a further aspect of this embodiment, the substrate temperature is about 350° C. In a further aspect of this embodiment, the substrate temperature is about 400° C. In a further aspect of this embodiment, the substrate temperature is about 425° C. In a further aspect of this embodiment, the substrate temperature is about 450° C. In a further aspect of this embodiment, the substrate temperature is about 475° C. In a further aspect of this embodiment, the substrate temperature is about 500° C. In a further aspect of this embodiment, the substrate temperature is about 525° C. In a further aspect of this embodiment, the substrate temperature is about 550° C. In a further aspect of this embodiment, the substrate temperature is about 600° C. In a further aspect of this embodiment, the substrate temperature is about 625° C. In a further aspect of this embodiment, the substrate temperature is about 650° C.

In one embodiment, the substrate temperature is set below the decomposition temperature of each of the precursors utilized in the process. In one embodiment, the substrate temperature is set near, at, or above the decomposition temperature of only one of the precursors utilized in the process where the process still performs as an ALD process (negligible CVD component). In one embodiment, the substrate temperature is set near, at, or above the decomposition temperatures of only two or more of the precursors utilized in the process where the process still performs as an ALD process (negligible CVD component). In one embodiment, the substrate temperature is set near, at, or above the decomposition temperatures of each of the precursors utilized in the process where the process still performs as an ALD process (negligible CVD component).

### Pressure

In another embodiment, the reactor pressure for depositions according to the disclosed and claimed process is between about 0.1 to about 100 Torr. In another embodiment, the reactor pressure for depositions according to the disclosed and claimed process is between about 2 to about 10 Torr.

In another embodiment, the reactor pressure for depositions according to the disclosed and claimed process is ≤to about 50 torr. In another embodiment, the reactor pressure for depositions according to the disclosed and claimed process is ≤to about 40 torr. In another embodiment, the reactor pressure for depositions according to the disclosed and claimed process is ≤to about 30 torr. In a further aspect of this embodiment, the reactor pressure is K to about 20 torr. In a further aspect of this embodiment, the reactor pressure is ≤to about 10 torr. In a further aspect of this embodiment, the reactor pressure is ≤to about 5 torr.

### Cycles and Order of Steps

In the above-described embodiments, as well as the other embodiments described herein, the described steps (e.g., (i) through (iv) or (i) through (v)) define one cycle of the method. It is to be understood that a cycle can be repeated until the desired thickness of a film is obtained. In one embodiment, the ALD method includes from about 5 to about 2000 cycles. In one embodiment, the ALD method includes from about 20 to about 1000 cycles. In one embodiment, the ALD method includes from about 50 to about 500 cycles. In one embodiment, the ALD method includes from about 100 to about 300 cycles. In one embodiment, the ALD method includes about 5 cycles. In one embodiment, the ALD method includes about 10 cycles. In one embodiment, the ALD method includes about 15 cycles. In one embodiment, the ALD method includes about 20 cycles. In one embodiment, the ALD method includes about 25 cycles. In one embodiment, the ALD method includes about 50 cycles. In one embodiment, the ALD method includes about 100 cycles. In one embodiment, the ALD method includes about 150 cycles. In one embodiment, the ALD method includes about 200 cycles. In one embodiment, the ALD method includes about 250 cycles. In one embodiment, the ALD method includes about 300 cycles. In one embodiment, the ALD method includes about 350 cycles. In one embodiment, the ALD method includes about 400 cycles. In one embodiment, the ALD method includes about 450 cycles. In one embodiment, the ALD method includes about 500 cycles. In one embodiment, the ALD method includes about 550 cycles. In one embodiment, the ALD method includes about 600 cycles. In one embodiment, the ALD method includes about 650 cycles. In one embodiment, the ALD method includes about 700 cycles. In one embodiment, the ALD method includes about 750 cycles. In one embodiment, the ALD method includes about 1000 cycles. In one embodiment, the ALD method includes about 1250 cycles. In one embodiment, the ALD method includes about 1500 cycles. In one embodiment, the ALD method includes about 1750 cycles. In one embodiment, the ALD method includes about 2000 cycles. In one embodiment, the ALD method includes about 2500 cycles.

In one embodiment, the ALD method provides fin free TMD growth (for example, for a superconducting channel layer in a device, such as a transistor) is performed by limiting the growth cycles to the onset of fin nucleation, which for MoO₂Cl₂+H₂S is about 400 cycles. As such, in one embodiment, the ALD method includes 50 cycles. In one embodiment, the ALD method includes about 100 cycles. In one embodiment, the ALD method includes about 150 cycles. In one embodiment, the ALD method includes about 200 cycles. In one embodiment, the ALD method includes about 250 cycles. In one embodiment, the ALD method includes about 300 cycles. In one embodiment, the ALD method includes the maximum number of cycles where fin nucleation is not yet manifested for that particular precursor combination and chamber hardware.

In the embodiments described herein, it is understood that the steps of the methods may be performed in a variety of orders, may be performed sequentially or concurrently (e.g., during at least a portion of another step), and any combination thereof. In addition, the respective step of supplying one or more of MoO₂Cl₂ and MoO₂Br₂ and nitrogen source may be performed by varying the duration of the time for supplying them to change film composition. For example, one embodiment runs the steps in the ALD cycle in the following order (iii), (iv), (i), (ii) repeated x times, and optionally followed by a step (iii).

### Exemplary Processes

### Films

The disclosed and claimed subject matter further includes films prepared by the methods described herein.

In one embodiment, the films formed by the methods described herein have trenches, vias or other topographical features with an aspect ratio of about 1 to about 750. In a further aspect of this embodiment, the aspect ratio is about 5 to about 500. In a further aspect of this embodiment, the aspect ratio is about 10 to about 350. In a further aspect of this embodiment, the aspect ratio is about 15 to about 300. In a further aspect of this embodiment, the aspect ratio is about 1 to about 20. In a further aspect of this embodiment, the aspect ratio is about 15 to about 200. In a further aspect of this embodiment, the aspect ratio is greater than about 5. In a further aspect of this embodiment, the aspect ratio is greater than about 10. In a further aspect of this embodiment, the aspect ratio is greater than about 20. In a further aspect of this embodiment, the aspect ratio is greater than about 30. In a further aspect of this embodiment, the aspect ratio is greater than about 50. In a further aspect of this embodiment, the aspect ratio is greater than about 70. In a further aspect of this embodiment, the aspect ratio is greater than about 100. In a further aspect of this embodiment, the aspect ratio is greater than about 150. In a further aspect of this embodiment, the aspect ratio is greater than about 200. In a further aspect of this embodiment, the aspect ratio is greater than about 300. In a further aspect of this embodiment, the aspect ratio is greater than about 400. In a further aspect of this embodiment, the aspect ratio is greater than about 500.

In another embodiment, the films formed by the methods described herein have a mobility of between about 1 to about 350. In a further aspect of this embodiment, the films have a mobility of about 5 to about 300. In a further aspect of this embodiment, the films have a mobility of about 10 to about 250. In a further aspect of this embodiment, the films have a mobility of about 20 to about 220. In a further aspect of this embodiment, the films have a mobility of about 30 to about 200. In a further aspect of this embodiment, the films have a mobility of about 40 to about 180. In a further aspect of this embodiment, the films have a mobility of about 15. In a further aspect of this embodiment, the films have a mobility of about 30. In a further aspect of this embodiment, the films have a mobility of about 50. In a further aspect of this embodiment, the films have a mobility of about 80. In a further aspect of this embodiment, the films have a mobility of about 100. In a further aspect of this embodiment, the films have a mobility of about 125. In a further aspect of this embodiment, the films have a mobility of about 150. In a further aspect of this embodiment, the films have a mobility of about 175. In a further aspect of this embodiment, the films have a mobility of about 200. In a further aspect of this embodiment, the films have a mobility of about 250. In a further aspect of this embodiment, the films have a mobility of about 300.

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods:

All materials including MoO₂Cl₂ were purchased from Versum Materials, and all films were deposited in Intermolecular A30 chambers.

### Example 1

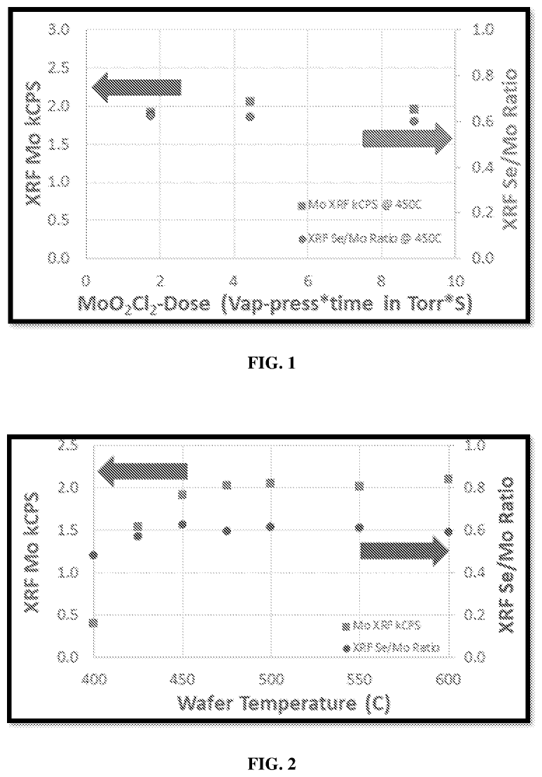

In Example 1 ALD 2D TMD growth of MoSe₂ was accomplished using MoO₂Cl₂+iPr₂Se with MoO₂Cl₂ pulse length saturation at 450° C. substrate temperature with MoO₂Cl₂ carrier flow set to 50 sccm, MoO₂Cl₂ pulse pressure set to 4 Torr, MoO₂Cl₂ purge length set to 50 s, iPr₂Se pulse time set to 10 s, iPr₂Se ampule temperature set at 29° C., iPr₂Se carrier flow set to 100 sccm, iPr₂Se pulse pressure set to 5 Torr, iPr₂Se purge length set to 50 s, and each deposition was run for 100 ALD cycles. As shown in FIG. 1, the deposited MoSe₂ thickness is shown as a function of MoO₂Cl₂ flux with saturation across an order of magnitude. Please note that the XRF Se/Mo ratio is the ratio of the raw counts, and that a raw counts ratio of ˜0.6 translates to an XPS Se/Mo ratio of ˜2.

The deposition process exhibits a flat deposition rate across the temperature range of the ALD deposition window. As shown in FIG. 2, the wafer temperature curve shows that ALD MoO₂Cl₂+iPr₂Se has an ALD window that stretches from about 450° C.-475° C. to at least about 600° C. substrate temperature at approximately constant thickness as measured by Mo XRF kCPS with MoO₂Cl₂ ampule temperature set to 65° C., MoO₂Cl₂ precursor pulse length set to 5 s, MoO₂Cl₂ carrier flow set to 50 sccm, MoO₂Cl₂ pulse pressure set to 4 Torr, MoO₂Cl₂ purge length set to 50 s, iPr₂Se pulse time set to 10 s, iPr₂Se ampule temperature set at 29° C., iPr₂Se carrier flow set to 100 sccm, iPr₂Se pulse pressure set to 5 Torr, iPr₂Se purge length set to 50 s, and each deposition is run for 100 ALD cycles. Again, please note that the XRF Se/Mo ratio is the ratio of the raw counts, and that a raw counts ratio of ˜0.6 translates to an XPS Se/Mo ratio of ˜2.

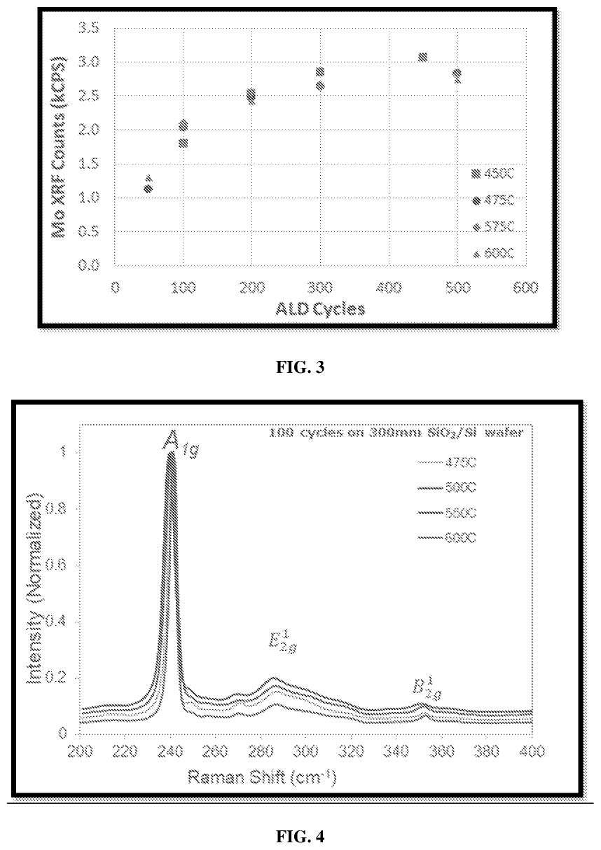

The ALD process also exhibits a self-limiting-layer-synthesis behavior in its growth curves. In FIG. 3, the ALD deposition of MoO₂Cl₂+iPr₂Se displays self-limiting-layer-synthesis behavior from about 475° C. to about 600° C. and asymptotically reaching similar thickness as measured by Mo XRF kCPS. The MoO₂Cl₂+iPr₂Se growth curves show saturation of thickness at around 500 cycles.

As shown in FIG. 4, the Raman spectroscopy shows that the MoSe₂ films are all 2D 2H-phase MoSe₂ films of good quality. In addition, as illustrated in FIG. 5, the analysis of the Raman FWHM vs. deposition temperature across the growth curve shown shows that the films have narrow FWHM and are stoichiometric or near stoichiometric as measured by XPS. In FIG. 5, the left image shows the A_{1g} FWHM versus ALD cycles at two temperatures and the right image shows the XPS Se/Mo ratio versus cycles at two temperatures.

### Example 2

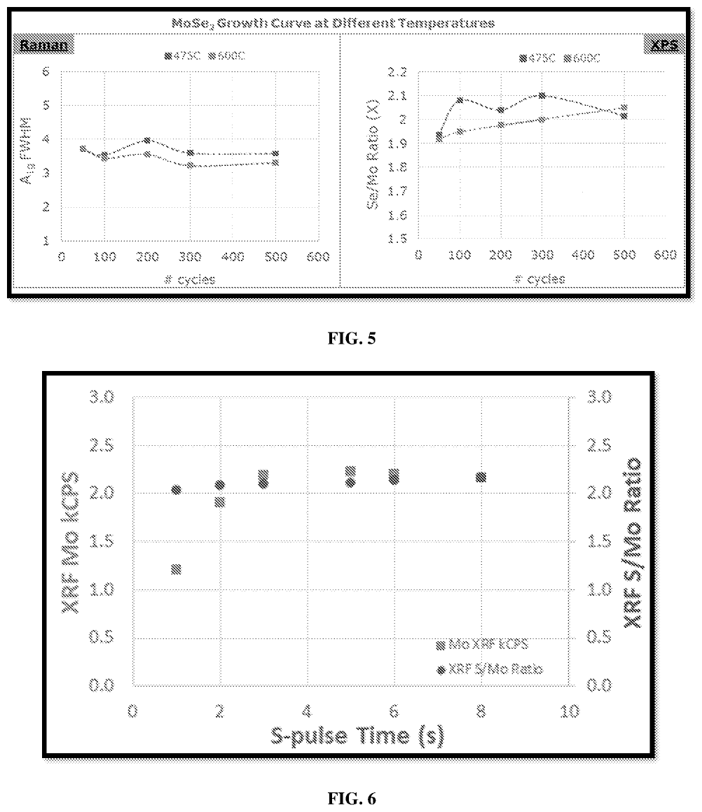

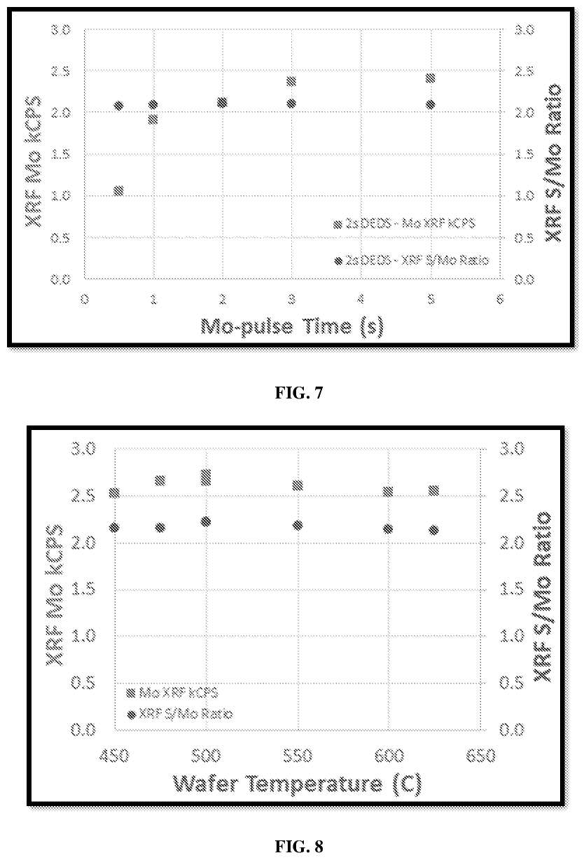

In Example 2 ALD 2D TMD growth of MoS₂ was accomplished using ALD MoO₂Cl₂+Et₂S₂ (diethyl disulfide or “DEDS”). FIG. 6 and FIG. 7 show the MoO₂Cl₂ and Et₂S₂ saturation curves measured at 600° C. for this example. In particular, FIG. 6 illustrates the DEDS saturation curve, showing saturation at about 3 s DEDS pulse length of MoS₂ (at 600° C. substrate temperature with (a) MoO₂Cl₂ pulse time at 5 s, MoO₂Cl₂Ar gas carrier flow at 50 sccm, (b) MoO₂Cl₂ purge time at 40 s, (c) MoO₂Cl₂Ar gas carrier flow at 50 sccm, (d) MoO₂Cl₂ purge time at 40 s, (e) DEDS Ar gas carrier flow at 100 sccm, (f) DEDS purge time at 60 s), using MoO₂Cl₂+Et₂S₂ in an embodiment (Example 2) of the disclosed and claimed subject matter. FIG. 7 illustrates the MoO₂Cl₂ saturation curve for Example 2 showing saturation at about 3 s MoO₂Cl₂ pulse length.

The ALD temperature curve shown in FIG. 8 shows that the ALD MoO₂Cl₂+Et₂S₂ from Example 2 has an ALD window from about 450° C. to at least 625° C. substrate temperature as measured by Mo XRF kCPS.

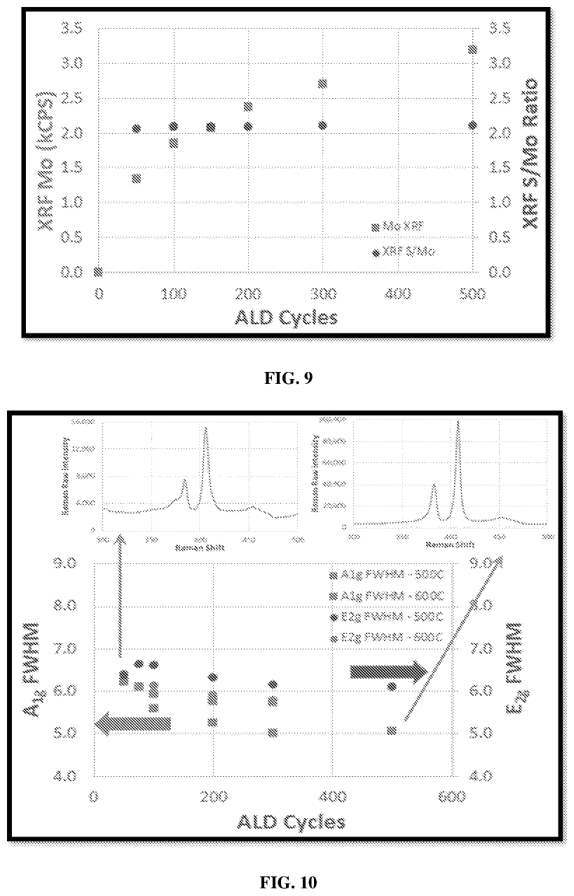

FIG. 9 illustrates that the ALD MoO₂Cl₂+Et₂S₂ growth curve exhibits a soft saturation behavior (i.e., a sublinear thickness vs ALD cycles instead of asymptotic curve vs ALD cycles) indicating that the etch component does not fully balance the deposition component out to 500 cycles. This deposition behavior allows better thickness targeting and better thickness uniformity at the right cycle counts compared to linear or supra-linear curves (no self-limiting-layer-synthesis-like behavior). As shown in FIG. 10, this deposition behavior yields a higher number of uniform monolayers at higher thickness. FIG. 10 plots the Raman A1g and E2g FWHM for the samples in FIG. 9 vs ALD cycles. This analysis shows that between 300 and 500 cycles, Raman reaches an optimally narrow FWHM for saturated MoO₂Cl₂+DEDS processes. It further includes the full Raman spectra for films deposited with 50 cycles and 500 cycles.

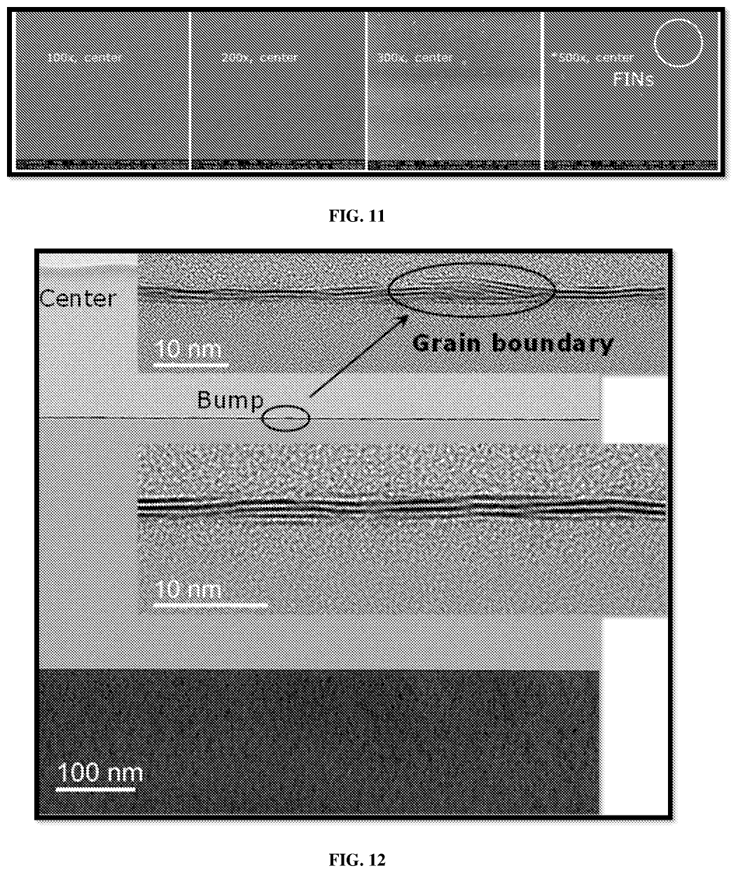

In the growth of high quality 2D Materials, it is desirable to have the growth start at well separated nucleation sites and grow sideways out from these sites until they coalesce with the surrounding islands, forming a continuous 2D layer. It is undesirable to have secondary islands starting to grow on top of the uncoalesced islands. FIG. 11 (SEM) and FIG. 12 (TEM) show the appearance of small new island growth on top of the coalesced layers after 300 ALD cycles and fin growth after 500 ALD cycles. FIG. 12 are TEM images of 100 ALD cycles of MoS₂, showing the fin-free MoS₂ over the area that TEM analysis is performed.

### Examples 3

Additional exemplary formulations are described in Table 1 which describes the relevant materials and applicable ALD conditions. Abbreviations: Chalcogenide (“CGD”)

TABLE 1

| | | | | MoO₂Cl₂ | | | | | | CGD | |
|---|---|---|---|---|---|---|---|---|---|---|---|
| | MoO₂Cl₂ | | MoO₂Cl₂ | Pressure | | CGD | | CGD | Wafer | Pressure | |
| Ex. | Pulse | | Purge | (Torr) | CGD | Pulse | | Purge | Temp. (° C.) | (Torr) | Cycles |
| 3 | 10 | s | 60 s | 6 | Et₂Se₂ | 25 | s | 60 s | 445 | 8.5 | 100 |
| 4 | 10 | s | 60 s | 6 | Et₂Se₂ | 25 | s | 60 s | 445 | 8.5 | 300 |
| 5 | 10 | s | 60 s | 6 | Et₂Se₂ | 25 | s | 60 s | 445 | 8.5 | 500 |
| 6 | 5 | s | 60 s | 2 | Et₂S | 0.25 | s | 60 s | 600 | 8.5 | 100 |
| 7 | 3 | s | 60 s | 2 | H₂S | 10 | s | 60 s | 500 | 8.5 | 100 |
| 8 | 3 | s | 60 s | 2 | H₂S | 10 | s | 60 s | 500 | 8.5 | 300 |
| 9 | 3 | s | 60 s | 2 | H₂S | 10 | s | 60 s | 600 | 8.5 | 100 |
| 10 | 3 | s | 60 s | 2 | H₂S | 10 | s | 60 s | 600 | 8.5 | 300 |

Although the disclosed and claimed subject matter has been described and illustrated with a certain degree of particularity, it is understood that the disclosure has been made only by way of example, and that numerous changes in the conditions and order of steps can be resorted to by those skilled in the art without departing from the spirit and scope of the disclosed and claimed subject matter.

1. A method for depositing Mo-containing films comprising:
(i) contacting a substrate with one or more of MoO₂Cl₂ and MoO₂Br₂ vapor in a deposition reactor;
(ii) purging any unreacted MoO₂Cl₂ or MoO₂Br₂ with inert gas;
(iii) contacting the substrate in the deposition reactor with one or more chalcogenide precursor of formula (i) R₁XR₂ or formula (ii) R₁XXR₂,
wherein
X=S, Se or Te, and
R₁ and R₂ are each independently one of hydrogen, an unsubstituted linear C₁-C₆ alkyl group, a linear C₁-C₆ alkyl group substituted with one or more halogen, a linear C₁-C₆ alkyl group substituted with an amino group, an unsubstituted branched C₃-C₆ alkyl group, a branched C₃-C₆ alkyl group substituted with one or more halogen, a branched C₃-C₆ alkyl group substituted with an amino group, an unsubstituted amine, a substituted amine, and —Si(CH₃)₃;
(iv) optionally purging of any unreacted chalcogenide precursor with inert gas; and
(v) optionally treating the substrate with one or more of H₂S gas and an H₂S plasma.

2-6. (canceled)

7. The method of claim 1, wherein the step of (i) contacting a substrate with one or more of MoO₂Cl₂ and MoO₂Br₂ vapor in a deposition reactor comprises pulsing the one or more of MoO₂Cl₂ and MoO₂Br₂ vapor from about 0.1 seconds to about 25 seconds.

8-19. (canceled)

20. The method of claim 1, wherein the step of (i) contacting a substrate with one or more of MoO₂Cl₂ and MoO₂Br₂ vapor in a deposition reactor comprises pulsing at an ampule temperature of from about 55° C. to about 300° C.

21-29. (canceled)

30. The method of claim 1, wherein the step of (i) contacting a substrate with one or more of MoO₂Cl₂ and MoO₂Br₂ vapor in a deposition reactor comprises pulsing at a gas flow of about 5 sccm to about 3000 sccm.

31-51. (canceled)

52. The method of claim 1, wherein the one or more chalcogenide precursor comprises a precursor of formula (i) R₁XR₂ wherein X=S, Se or Te, and R₁ and R₂ are each independently one of hydrogen, methyl, ethyl, n-propyl, iso-propyl, n-butyl, sec-butyl, iso-butyl and tert-butyl.

53. The method of claim 1, wherein the one or more chalcogenide precursor comprises a precursor of formula (ii) R₁XXR₂ wherein X=S, Se or Te, and R₁ and R₂ are each independently one of hydrogen, methyl, ethyl, n-propyl, iso-propyl, n-butyl, sec-butyl, iso-butyl and tert-butyl.

54. The method of claim 1, wherein X is S.

55. The method of claim 1, wherein X is Se.

56. The method of claim 1, wherein X is Te.

57-64. (canceled)

65. The method of claim 1, wherein the one or more chalcogenide precursor comprises one or more of iBu₂S, iPr₂S, iPr₂Se, Et₂S₂, Et₂Se, tBuSH, H₂Se, H₂S, H₂Te, Et₂Te and iPr₂Te.

66-75. (canceled)

76. The method of claim 1, wherein the step of (iii) contacting the substrate in the deposition reactor with one or more chalcogenide precursor comprises pulsing the precursor from about 0.5 seconds to about 25 seconds.

77-81. (canceled)

82. The method of claim 1, wherein the step of (iii) contacting the substrate in the deposition reactor with one or more chalcogenide precursor comprises pulsing the precursor at a vapor pressure of from about 0.3 Torr to about 15,000 Torr.

83-88. (canceled)

89. The method of claim 1, wherein the step of (iii) contacting the substrate in the deposition reactor with one or more chalcogenide precursor comprises pulsing the precursor at a carrier gas flow from about 0 sccm to about 3000 sccm.

90-109. (canceled)

110. The method of claim 1, wherein the step of (v) treating the substrate with one or more of H₂S gas and an H₂S plasma comprises treating with H₂S plasma wherein the H₂S plasma is directly generated in the reactor.

111. The method of claim 1, wherein the step of (v) treating the substrate with one or more of H₂S gas and an H₂S plasma comprises treating with H₂S plasma wherein the H₂S plasma is generated outside of the reactor and then supplied into the reactor.

112. The method of claim 1, wherein the substrate comprises one or more of aluminum oxide (Al₂O₃), aluminum nitride (AlN), silicon oxide (SiO₂), silicon oxynitride, silicon nitride (Si₃N₄), zirconium oxide (ZrO₂) and hafnium oxide (HfO₂).

113-144. (canceled)

145. The method of claim 1, wherein the reactor pressure is between about 0.1 to about 100 Torr.

146-182. (canceled)

183. A molybdenum-containing film deposited by the process of claim 1.

184-219. (canceled)

220. The method of claim 1, wherein the step of (i) contacting a substrate with one or more of MoO₂Cl₂ and MoO₂Br₂ comprises contacting the substrate with MoO₂Cl₂.

221. (canceled)

222. (canceled)

223. The method of claim 1, wherein the step of (i) contacting a substrate with one or more of MoO₂Cl₂ and MoO₂Br₂ comprises contacting the substrate with MoO₂Br₂.

224. (canceled)

225. (canceled)
